(19) United States
(12) Patent Application Publication
(10) Pub. No.: US 2013/0334405 A1
(43) Pub. Date: Dec. 19, 2013

(54) OPTICAL RECEIVING CIRCUIT, DRIVING DEVICE FOR VIBRATION-TYPE ACTUATOR, AND SYSTEM

(71) Applicant: CANON KABUSHIKI KAISHA, Tokyo (JP)

(72) Inventor: Takeshi Iwasa, Tokyo (JP)

(21) Appl. No.: 13/914,930

(22) Filed: Jun. 11, 2013

(30) Foreign Application Priority Data
Jun. 15, 2012 (JP) 2012-135448
May 20, 2013 (JP) 2013-106486

(51) Int. Cl. G01R 33/36; G01J 1/44

(52) U.S. Cl. CPC G01R 33/36; G01J 1/44
USPC 250/214 A; 250/214.1

(57) ABSTRACT

An optical receiving circuit of an embodiment of the present invention includes a photo detector configured to receive an optical pulse signal and a load connected to the photo detector. A circuit comprises the photo detector and a resistance component of the load. This circuit is configured to output a non-pulse signal.

### BACKGROUND OF THE INVENTION

1. Field of the Invention

The present disclosure relates to an optical receiving circuit, a driving device for a vibration-type actuator, the driving device using the optical receiving circuit, and a system using the driving device. In particular, the present disclosure relates to an optical receiving circuit on the receiving side of an optical communication line, a driving device for a vibration-type actuator, the driving device using the optical receiving circuit, and a system using the driving device.

2. Description of the Related Art

In recent years, medical robotic devices, such as manipulators, have been studied actively. One typical example is a medical system that uses a magnetic resonance imaging (MRI) apparatus, and the medical system enables a user to control the position of a robotic arm of a manipulator and perform an accurate biopsy and treatment while viewing an MR image. MRI is a medical system for providing a site to be measured of a subject (specimen) with a static magnetic field and an electromagnetic wave generated by a specific radio-frequency magnetic field, creating an image by applying the nuclear magnetic resonance phenomenon induced by the provision inside the subject, and obtaining information on the specimen.

Because the MRI is using high magnetic fields, it is not possible to use an electromagnetic motor that includes a ferromagnet as a power source for a robotic arm. Thus a vibration-type actuator, typified by an ultrasonic motor, is suitable for the power source. Radio-frequency noise generated by a controller for the vibration-type actuator also has an influence on an MR image, and thus it is necessary to significantly suppress or block the noise from the controller.

Japanese Patent Laid-Open No. 2000-184759 describes a change in the amount of harmonics generated in accordance with a pulse width of a driving waveform of a vibration-type actuator and also illustrates a circuit configuration in which the voltage of a pulse signal is boosted by a transformer. Like in this case, a vibration-type actuator is typically driven by a pseudo sine wave in which the waveform of a pulse voltage is rounded by the use of an inductor element or other elements. Because the waveform is generated based on the pulse voltage, the pseudo sine wave has a waveform in which, in addition to a lowest-order fundamental wave, a harmonic with a frequency that is an integral multiple of that of the fundamental wave is superimposed.

“Basic Contract Accomplishment Report of Research and Development of Miniature Surgical Robotic System Achieving Future Medical Treatment,” New Energy and Industrial Technology Development Organization (NEDO), discloses a configuration in which a controller and a driving circuit for a vibration-type actuator are arranged outside a magnetically shielded room and are connected to the vibration-type actuator inside the magnetically shielded room with a double-shielded electrical cable. This configuration further includes a line filter in a portion where the cable passes through the wall, and noise can be prevented from entering the magnetically shielded room. To reduce electromagnetic noise caused by a current flowing in the vibration-type actuator, the vibration-type actuator is placed in an aluminum case to be subjected to electromagnetic shielding.

A known driving circuit illustrated in Japanese Patent Laid-Open No. 2000-184759 can smooth a driving waveform to some extent using a filter characteristic formed by an inductor on the secondary side of the transformer and a damping capacitance of the vibration-type actuator. That is, harmonic components can be suppressed to some extent. However, because the last output stage is also made of a switching circuit, a waveform immediately after being output from the circuit contains many superimposed harmonic components in principle. Thus when the vibration-type actuator is activated in a magnetically shielded room where the MRI apparatus is placed, a problem arises in that noise is mixed in an MR image. In addition, because such a driving circuit has a non-flat frequency response characteristic, the waveform is also greatly changed by a change in impedance caused by a change in vibration amplitude of the vibration-type actuator. Accordingly, the frequency characteristic of noise may vary depending on the driving condition.

In the configuration described in the above-mentioned report by NEDO, the electric cable to the vibration-type actuator is double-shielded, and the line filter is disposed in the connection port to the inside of the magnetically shielded room. However, because the vibration-type actuator is electrically connected to the driving circuit and the controller, it is difficult to completely block radio-frequency noise. Thus when the vibration-type actuator is driven in the vicinity of the MRI apparatus, noise may be mixed in an MR image. When the length of the wiring of the vibration-type actuator is long, the load capacity dependent on the wiring may be increased, and power consumption may be increased. One approach to suppressing electromagnetic noise from a unit configured to generate a driving waveform signal for the vibration-type actuator can be a method of converting a driving waveform signal into an optical pulse signal and transmitting it. In particular, when a vibration-type actuator inside a magnetically shielded room where an MRI apparatus is disposed is driven, one possible effective way can be using not a switching circuit but a linear amplifier in an output stage of the driving circuit after an optical pulse signal is converted into an electrical signal. In this case, however, if the number of vibration-type actuators and the number of channels of a circuit are increased, it is necessary to further include a high-speed photoelectric conversion circuit that has a wide range sufficiently for transmission of a driving pulse signal and a digital-to-analog converter or a filter circuit for converting a pulse signal into a non-pulse signal. Accordingly, a problem arises in that the driving device tends to have a large size and be expensive.

### SUMMARY OF THE INVENTION

An embodiment of the present invention provides a low-cost optical receiving circuit configured to receive an optical pulse signal and capable of reducing harmonic components.

An optical receiving circuit of an embodiment of the present invention includes a photo detector configured to receive an optical pulse signal and a load connected to the photo detector. A circuit comprising the photo detector and a resistance component of the load outputs a non-pulse signal.

Further features of the present invention will become apparent from the following description of exemplary embodiments with reference to the attached drawings.

### BRIEF DESCRIPTION OF THE DRAWINGS

FIG. 1 is a diagram that illustrates a system outline according to a first embodiment.

FIG. 2 is a diagram that illustrates a configuration of a vibration-type actuator according to the first embodiment.

FIG. 3 is a diagram that illustrates an outline of a driving circuit according to the first embodiment.

FIG. 4A is a diagram that illustrates an outline of an optical receiving circuit according to the first embodiment, and FIG. 4B is a plot that schematically illustrates a characteristic of a photoelectric conversion element.

FIG. 5 is a diagram that illustrates an outline of an operating waveform of each of portions in the first embodiment.

FIG. 6 is a diagram that illustrates a system outline according to a second embodiment.

### DESCRIPTION OF THE EMBODIMENTS

An optical receiving circuit according to an embodiment of the present invention can be used in particular in a driving device (driving circuit) for a vibration-type actuator. The optical receiving circuit can also be used as not only a driving device for a vibration-type actuator but also a driving device for an illuminating apparatus and other apparatuses. A driving device including the optical receiving circuit according to an embodiment of the present invention can be used in a system that includes an MRI apparatus and other apparatuses. An MRI apparatus irradiates a specimen with a radio frequency (RF) pulse, and receives an electromagnetic wave generated by the specimen in response to the irradiation using a high-sensitivity reception coil (RF coil). Then the MRI apparatus obtains a magnetic resonance (MR) image as information on the specimen on the basis of a reception signal from the reception coil. The vibration-type actuator and the driving device therefor according to an embodiment of the present invention are not limited to application to the above-described medical system. Both are also applicable to an apparatus or system for measuring physical quantities relating to an electromagnetic wave and magnetism (e.g., magnetic flux density “tesla [T]”, magnetic field strength “A/m,” and electrical field strength “V/m”).

Embodiments of the present invention are described below with reference to the drawings. In the embodiments below, an example in which a driving device for a vibration-type actuator used inside an MRI apparatus includes an optical receiving circuit of the present invention is described. The embodiments below do not limit the invention relating to the scope of claims, and not all of the combinations of characteristics described in the embodiments are necessary for the solutions in the invention.

### First Embodiment

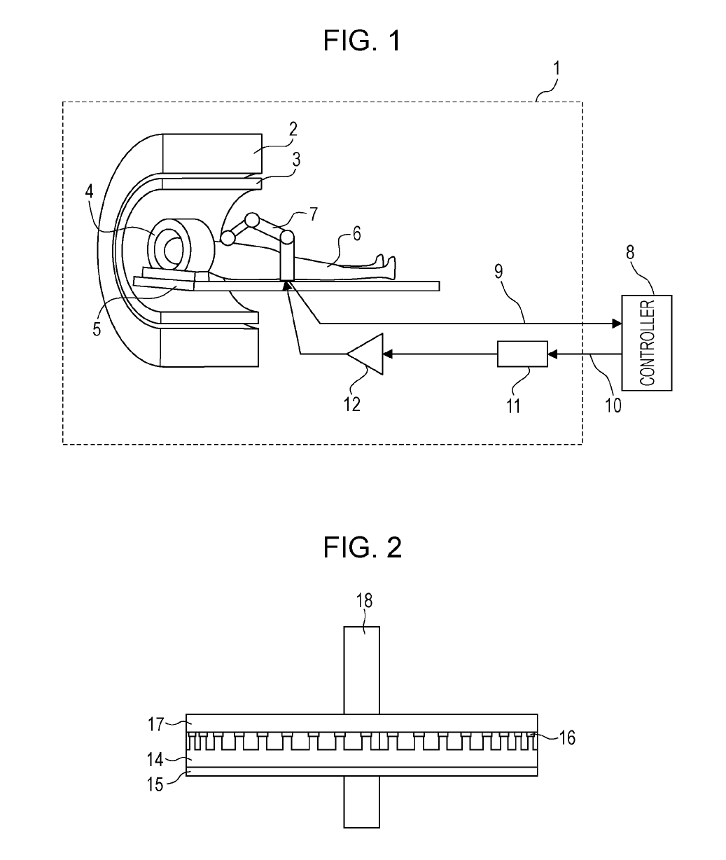

FIG. 1 is a diagram that illustrates a configuration of a medical system according to a first embodiment of the present invention. This system performs functional magnetic resonance imaging (fMRI). fMRI is a technique of visualizing changes in blood flow caused by brain and spine activity using an MRI apparatus. This system changes a contact stimulus on a time-series basis by moving a robotic arm using a vibration-type actuator and measures corresponding changes in blood flow inside the brain. Aside from a contact stimulus, various types of stimuli, such as a visual one and an auditory one, are studied as stimuli used in the system. In particular, when a robotic arm or another tool is moved inside the MRI apparatus, electromagnetic noise produced by a driving source is reduced and members are demagnetized by magnetically shielding.

### (Basic Configuration of MRI Apparatus)

First, the configuration of a system that includes an MRI apparatus is described as a medical system according to the present embodiment with reference to FIG. 1. The system to which an embodiment of the present invention is applicable includes at least a measurement unit disposed inside a magnetically shielded room 1 and a controller 8 disposed outside the magnetically shielded room 1.

The MRI apparatus is sensitive in particular to electromagnetic noise in the vicinity of a frequency called the Larmor frequency, which is determined in accordance with a magnetic field strength specific to the apparatus. The Larmor frequency is a frequency of precession of magnetic dipole moment of atomic nuclei inside the brain of a subject 6. For the magnetic field strength 0.2 T to 3 T, which is clinically used by an MRI apparatus in general, the Larmor frequency ranges from 8.5 MHz to 128 MHz. Thus it is necessary to significantly reduce the occurrence of electromagnetic noise in frequencies in that range in devices operating in a magnetically shielded room. However, because the controller 8, in which a central processing unit (CPU) or a field-programmable gate array (FPGA) is used, typically operates with an external clock of approximately 10 MHz to 50 MHz, electromagnetic noise resulting from that clock signal largely overlaps the range of the Larmor frequency when its harmonic waves are included. Because of this, the measurement unit configured to measure a change in weak magnetic field occurring inside the brain is disposed inside the magnetically shielded room 1, which blocks the influences of external noise.

The measurement unit of the MRI apparatus includes at least a superconducting magnet 2 for producing a static magnetic field, a gradient coil 3 for producing a gradient magnetic field to identify a three-dimensional position, an RF coil 4 for irradiating the subject 6 with an electromagnetic wave and receiving the electromagnetic wave, and a table 5 for the subject 6. The RF coil 4 corresponds to a receiving portion. The superconducting magnet 2 and the gradient coil 3 are both cylindrical in actuality, and both are illustrated in FIG. 1 such that their half portions are removed. The RF coil 4 is specialized for measurement of MR imaging inside the brain, and is constructed in a tubular form so as to cover the head of the subject 6 lying on the table 5. The measurement unit of the MRI apparatus produces gradient magnetic fields in various sequences and emits electromagnetic waves in accordance with a control signal from a control portion (not illustrated) disposed outside the magnetically shielded room 1. The outside control portion (not illustrated) obtains various kinds of information on the inside of the brain using a reception signal from the RF coil 4. This control portion, which is used for controlling electromagnetic waves, may be included in the controller 8.

A robotic arm 7 is fixed on the table 5 in the measurement unit. The robotic arm 7 can move with three degrees of freedom of two joints and pivoting of a base, and can cause a contact ball at the tip of the arm to be pressed in contact with any location of the subject 6 by any pressing force and can provide the subject 6 with time-series stimuli. Each of the joints and the pivoting base of the robotic arm 7 is equipped with the vibration-type actuator illustrated in FIG. 2, a rotation sensor, and a force sensor (both of which are not illustrated). A signal of each of the rotation sensor and the force sensor is converted into an optical pulse signal, and it is transmitted to the controller 8, which is disposed outside the magnetically shielded room 1, through an optical fiber 9. Each of the joints of the robotic arm 7 is equipped with the vibration-type actuator, and the vibration-type actuator is a mechanism for directly driving the joint. Thus the entire stiffness is high, and an operation of the robotic arm 7 can provide the subject 6 with various stimuli in a wide frequency range. The main structure of the robotic arm 7, including the vibration-type actuator, is made of a nonmagnetic material, and it is designed to minimize interference with a static magnetic field produced by the superconducting magnet 2.

In actual measurement, first, the subject 6 is asked to grab the tip of the robotic arm 7 with his or her hand and not to move his or her arm as much as possible. Then, the magnitude of a force, the pattern of the direction thereof, and other elements are changed on a time-series basis while the force is produced by the robotic arm 7, and changes in blood flow inside the brain of the subject 6 are measured. For such a measurement, because it is necessary to continuously exert the force, driving the robotic arm 7 continues.

The controller 8 outputs a driving signal (driving waveform) for driving the vibration-type actuator in accordance with a result of comparison between a time-series signal for proving the subject 6 with a stimulus with a preset route and a preset pressing force and information from the rotation sensor and the force sensor. The driving signal is a pulse signal in which a sine wave as waveform data is pulse-width modulated. This pulse-width modulated signal is converted into an optical pulse signal inside the controller 8, and the optical pulse signal is transmitted into the magnetically shielded room 1 through an optical fiber 10. The optical fiber 10 corresponds to an optical transmission unit. That is, in FIG. 1, the controller 8 includes a waveform generating unit configured to generate a driving waveform and an optical transmitting circuit configured to convert the driving waveform into an optical pulse signal.

A photoreceiver 11 converts an optical pulse signal output from the controller 8 into an electrical signal. The photoreceiver 11 corresponds to an optical receiving circuit. The electrical signal output from the photoreceiver 11 is a non-pulse signal. Specifically, harmonic components of a pulse-width modulated signal are removed, and a resultant sinusoidal signal is output.

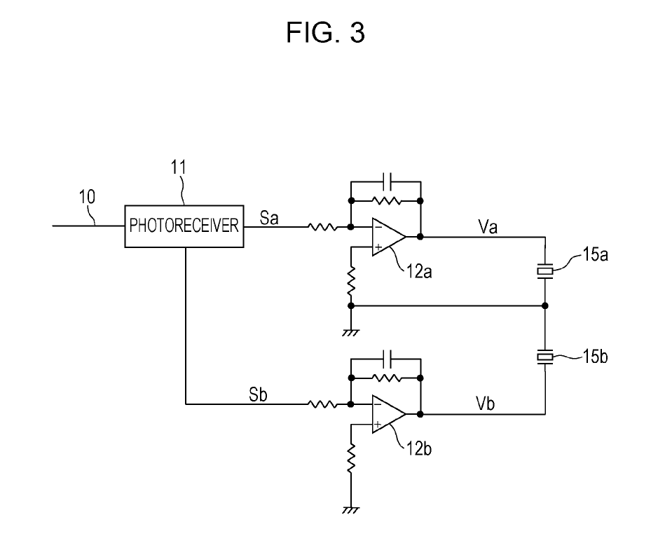

A linear amplifier 12 linearly amplifies a sinusoidal signal output from the photoreceiver 11 and applies it to the vibration-type actuator. The linear amplifier 12 corresponds to a linear amplification unit. Because the linear amplifier 12 is used, harmonic components contained in a driving voltage in the present embodiment are smaller than those when a switching amplifier is used. Because an output impedance of the linear amplifier is low, even if the impedance characteristic of the vibration-type actuator changes, a change in waveform of the driving voltage applied to the vibration-type actuator is small. In the present embodiment, the photoreceiver 11 and the linear amplifier 12 constitute a driving circuit. The details of the driving circuit are described below with reference to FIG. 3.

### (Configuration of Vibration-Type Actuator)

The configuration of the vibration-type actuator applicable to an embodiment of the present invention is described below. FIG. 2 is a diagram that illustrates an example configuration of the vibration-type actuator. The vibration-type actuator in the present embodiment includes a vibrator and a driven member.

The vibrator includes an elastic member 14 and a piezoelectric member 15. The piezoelectric member 15 is a piezoelectric element (electrical-to-mechanical energy conversion element). The elastic member 14 has a ring structure that has the shape of the teeth of a comb on one surface. The piezoelectric member 15 is attached to another surface of the elastic member 14. The top surface of the protrusions of the shape of the comb teeth of the elastic member 14 is attached to a friction member 16. The driven member is a rotor 17. The rotor 17 has a disc-shaped structure that is pressed into contact with the elastic member 14 with the friction member 16 disposed therebetween by a pressing unit (not illustrated).

When an alternating voltage (driving voltage) is applied to the piezoelectric member 15 in the vibration-type actuator, vibration occurs in the elastic member 14. Specifically, a travelling oscillatory wave that travels along the circumference of the ring occurs in the elastic member 14. This vibration produces a frictional force between the rotor 17 and the friction member 16, and the frictional force rotates the rotor 17 relative to the elastic member 14. A rotation shaft 18 is fixed on the center of the rotor 17, and rotates together with the rotor 17. In the present embodiment, this vibration-type actuator is arranged on each of the two joints, which are indicated by circles in FIG. 1, and the connection between the table 5 and the base of the robotic arm 7 to enable rotation of each of the two joints and pivot motion of the overall portion.

### (Basic Configuration of Driving Circuit for Vibration-Type Actuator)

A driving circuit that is a device for driving the vibration-type actuator according to the present embodiment is described next in detail with reference to FIG. 3. FIG. 3 is a diagram that illustrates the driving circuit according to the present embodiment. The driving circuit for the vibration-type actuator in the present embodiment, includes the photoreceiver 11 and linear amplifiers 12a and 12b. In the following description, when it is not necessary to distinguish between the linear amplifiers 12a and 12b, they are represented as the linear amplifier 12. The linear amplifier 12 includes a Class A or AB amplifier, and outputs a waveform with small harmonic distortion.

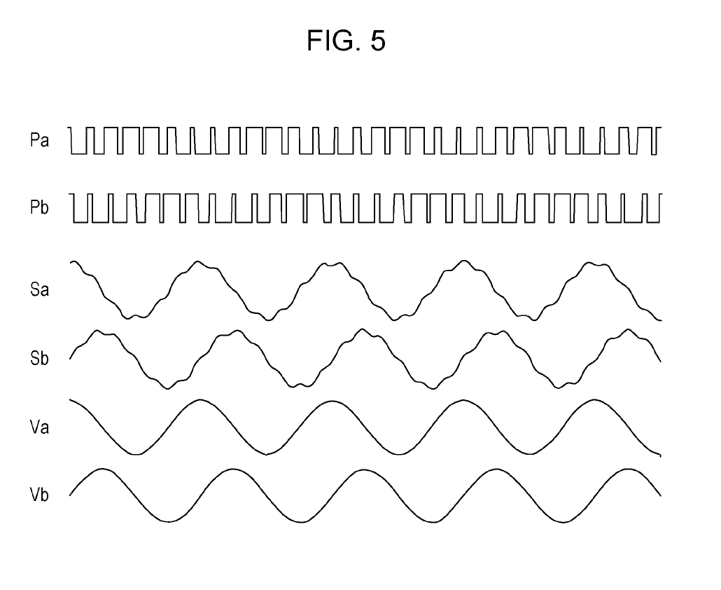

As described above, in the present embodiment, pulse signals Pa and Pb (see FIG. 5), each of which a sine wave is pulse-width modulated, are converted into optical pulse signals by the above-described optical transmitting circuit. The photoreceiver 11 receives the optical pulse signals through the optical fiber 10, and converts each of the optical pulse signals into an electrical signal (non-pulse signal). In a typical circuit configuration, an output of the photoreceiver 11 having a wide range characteristic sufficiently for a pulse signal is input into a low-pass filter circuit, and a carrier wave of a pulse-width modulated signal is removed. In contrast, in the present embodiment, the photoreceiver 11 also has a filter characteristic. Specifically, the photoreceiver 11 removes a carrier wave of a pulse-width modulated signal by the low-pass filter function thereof, and outputs two sinusoidal signals Sa and Sb having different phases.

Each of the linear amplifiers 12a and 12b is an inverting linear amplifier that is band-limited with a capacitor. When the filter order of the photoreceiver 11 is low and the above-described carrier wave components remain in the sinusoidal signals Sa and Sb, the carrier wave components are further attenuated by the frequency characteristics of the linear amplifiers 12a and 12b, and then the driving voltages are applied to piezoelectric members 15a and 15b. If the filter characteristic of the photoreceiver 11 is sufficiently limited to a frequency range in advance, the linear amplifiers 12a and 12b may not have the configuration in which the frequency range is limited using the capacitor, unlike the present embodiment. The linear amplifier 12 is not limited to the configuration in which a non-pulse signal output from the photoreceiver 11 is directly input into the linear amplifier 12. Another circuit may be disposed between the linear amplifier 12 and the photoreceiver 11. That is, the linear amplifier 12 may receive a signal based on a non-pulse signal output from the photoreceiver 11.

### (Configuration of Optical Receiving Circuit)

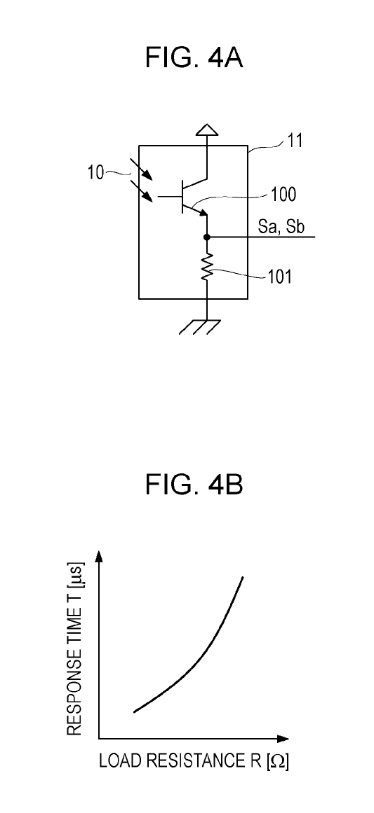

The configuration of the photoreceiver 11, which is the optical receiving circuit, according to the present embodiment is described in detail below. In a configuration of a typical optical receiving circuit, an output of the photoreceiver 11 having a wide range characteristic sufficiently for a pulse signal is input into a low-pass filter circuit, and a carrier wave in a pulse-width modulated signal is removed. In contrast, the photoreceiver 11 in the present embodiment also has a low-pass filter characteristic. FIG. 4A is a diagram that illustrates only one channel of an inner circuit in the photoreceiver 11. FIG. 4B is a plot that schematically illustrates a load resistance-response speed characteristic of a photoelectric conversion element 100.

The circuit illustrated in FIG. 4A includes the photoelectric conversion element 100 and a load resistance 101 (resistance element) as a load connected to the photoelectric conversion element. The photoelectric conversion element 100 corresponds to a photo detector. When a signal input through the optical fiber 10 enters the photoelectric conversion element 100, which includes a phototransistor, a current flows from the collector side to the emitter side. This current is converted into a voltage by the load resistance 101, and the voltage is output as output signals Sa and Sb. The load resistance 101 corresponds to a load for the photoelectric conversion element 100. Here, as illustrated in FIG. 4B, which is a log-log graph, typically, the response speed of the photoelectric conversion element 100 reduces (the length of the response time increases) with an increase in the value of the load resistance 101. That is, the photoelectric conversion element 100 has a characteristic in which the band reduces with an increase in the value of resistance of the load.

As described above, in a typical optical receiving circuit, the performance of the photoelectric conversion element 100 is increased such that its band is as wide as possible, and a constant (value of resistance) of the load resistance 101 is selected such that it does not interfere with this performance. In contrast, an embodiment of the present invention turns this characteristic to advantage. That is, the value of resistance of the load is selected such that the band of an output signal is limited. This enables the circuit comprising the photoelectric conversion element 100 and the resistance component of the load resistance 101 to output a non-pulse signal. That is, this circuit serves as a low-pass filter to a pulse-width modulated signal.

Specifically, in the present embodiment, the circuit comprising the photoelectric conversion element 100 and the resistance component of the load resistance 101 is configured such that at least a fundamental wave component of a sine wave that is a modulation signal of each of the pulse signals Pa and Pb is output as a non-pulse signal. That is, this circuit outputs an electrical signal corresponding to at least a fundamental wave component of a modulation signal in an optical pulse signal received by the photoelectric conversion element 100. More specifically, the circuit comprising the photoelectric conversion element 100 and the resistance component of the load resistance 101 functions as a filter to the carrier frequency of the pulse width modulation.

FIG. 5 schematically illustrates distortion of an operating waveform in each of the portions illustrated in FIG. 3. In the sinusoidal waves Sa and Sb output from the photoreceiver 11, there are remaining signals that are components of the carrier wave and cannot be removed from the pulse signals Pa and Pb by the optical receiving circuit, other than the fundamental components of sine waves. That is, at least a fundamental wave component in a modulation signal is output from the photoreceiver 11. The carrier wave component contained in each of the sinusoidal signals Sa and Sb is further attenuated by the low-pass filter characteristic of the linear amplifier 12, as indicated as the alternating voltages Va and Vb. Accordingly, the driving voltage applied to the piezoelectric member 15 contains substantially no carrier wave component.

The resistance element is used as the load in the optical receiving circuit in the present embodiment. The load in an embodiment of the present invention is not limited to the resistance element. Examples of the load can include a circuit configured to convert a current output from the photoelectric conversion element 100 into a voltage signal, such as an active load in which a transistor is used.

To make the advantage of the low-noise circuit in the present embodiment more effective, a battery may also be used as the power supply for the circuit inside the magnetically shielded room 1. This case may be useful in terms of the circuit configuration because the common-mode noise mixing through the power supply line can be blocked in theory.

In addition, it may be useful that, if the driving circuit includes a plurality of optical receiving circuits, one or more optical receiving circuits among the plurality of optical receiving circuits be packaged as an optical receiving module. It may be useful that a plurality of optical receiving circuits be placed in the same package as an optical receiving module. Packaging the optical receiving circuits as a module increases usability when many identical circuits are arranged in parallel.

In the present embodiment, a pulse signal output from the waveform generating unit in the controller 8 has a waveform in which a sine wave is pulse-width modulated. The pulse signal may have waveforms obtained by other pulse modulation schemes. For example, even with a waveform produced using pulse-density modulation (PDM), typified by ΔΣ modulation, or pulse-amplitude modulation (PAM), at least an original sine wave is obtainable when its harmonic components, such as its carrier wave, are removed using the filter characteristic of the optical receiving circuit.

As described above, because the optical receiving circuit according to the present embodiment turns the load resistance-response band characteristic of the photoelectric conversion element 100 to advantage and functions as a low-pass filter circuit to a pulse signal, its harmonic components can be reduced. A problem arising when the number of vibration-type actuators and the number of channels of a circuit are increased can also be solved. Specifically, it is not necessary to further include a high-speed photoelectric conversion circuit that has a wide range sufficiently for transmission of a pulse signal, a digital-to-analog converting circuit for converting a pulse signal into a non-pulse signal, and a filter circuit. Accordingly, an increase in the size of the circuit can be avoided. Thus the apparatus can be miniaturized, and an increase in cost can also be suppressed.

### Second Embodiment

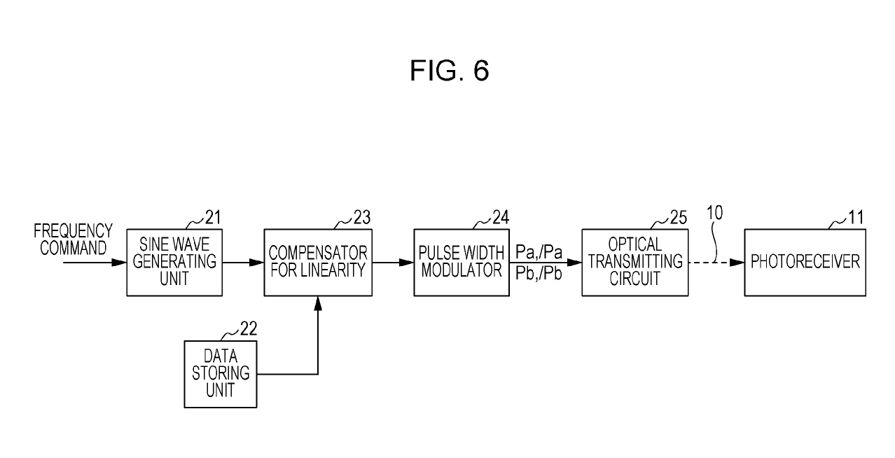

A second embodiment of the present invention is described next with reference to FIG. 6. The portions in the present embodiment other than the inner configuration of the waveform generating unit configured to generate a driving waveform are substantially the same as those in the first embodiment, and the detailed description thereof is omitted.

FIG. 6 is a diagram that illustrates an outline of a system configuration according to the present embodiment. The waveform generating unit in the present embodiment includes at least a sine wave generating unit 21, a compensator for linearity 23, a data storing unit 22, and a pulse width modulator 24. The sine wave generating unit 21 generates a sinusoidal signal in accordance with a frequency command from a command unit (not illustrated). The data storing unit 22 stores linearity compensation data for use in correcting nonlinearity of the photoreceiver 11 to ensure linearity, the linearity compensation data obtained by measurement in advance.

Here, a reason why linearity compensation data is used is described. The features of the photoelectric conversion elements 100 vary, and the pulse width of a pulse-width modulated signal varies from its ideal state, that is, the linearity may decrease (that is, the feature may be nonlinear). Specifically, the nonlinearity indicates that, in converting an optical pulse signal into an electrical signal, the optical pulse width and the amplitude value of the non-pulse electrical signal are not proportional (linear). At this time, a sinusoidal signal to be applied to the piezoelectric member 15 is in a distorted state. To make the sinusoidal signal to be applied to the piezoelectric member 15 near to its ideal state, it is necessary to correct the pulse width of a pulse-width modulated signal as appropriate. To this end, measuring linearity compensation data for each photoelectric conversion element 100 and storing it into the data storing unit 22 enables satisfactory linearity in actual use to be ensured. To ensure more satisfactory linearity, it may be useful that compensation data be individually measured for each photoelectric conversion element 100.

The compensator for linearity 23 corrects sinusoidal signals input from the sine wave generating unit 21 on the basis of linearity compensation data read from the data storing unit 22. The corrected sinusoidal signals are made to pulse signals Pa, /Pa, Pb, and /Pb by the pulse width modulator 24. Each of these pulse signals is converted into an optical pulse signal as a driving waveform by an optical transmitting circuit 25. The optical signals are output to the optical fiber 10. The photoreceiver 11, which is the optical receiving circuit, and the portions thereafter have substantially the same configurations as in the first embodiment, and the description thereof is omitted.

As described above, in the present embodiment, the inclusion of the compensator for linearity configured to correct a sinusoidal signal using previously prepared linearity compensation data corresponding to each photoelectric conversion element enables the vibration-type actuator to be driven with a sine wave using the optical receiving circuit with good linearity.

According to the present invention, an optical receiving circuit configured to receive an optical signal and capable of reducing harmonic components can be provided by turning the load resistance-response band characteristic of a photo detector to advantage.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-135448 filed Jun. 15, 2012 and No. 2013-106486 filed May 20, 2013, which are hereby incorporated by reference herein in their entirety.

What is claimed is:

1. An optical receiving circuit comprising:
a photo detector configured to receive an optical pulse signal; and
a load connected to the photo detector,
wherein a circuit comprising the photo detector and a resistance component of the load outputs a non-pulse signal.

2. The optical receiving circuit according to claim 1, wherein the circuit comprising the photo detector and the resistance component of the load functions as a low-pass filter.

3. The optical receiving circuit according to claim 1, wherein the circuit comprising the photo detector and the resistance component is configured to output, as the non-pulse signal, an electrical signal corresponding to at least a fundamental wave component of a modulation signal in the optical pulse signal.

4. The optical receiving circuit according to claim 1, wherein a value of resistance of the load is a value of resistance at which the circuit comprising the photo detector and the resistance component is capable of outputting the non-pulse signal.

5. The optical receiving circuit according to claim 1, wherein the load is a resistance element.

6. An optical receiving module comprising a plurality of the optical receiving circuits according to claim 1, wherein one or more of the plurality of optical receiving circuits are packaged.

7. A driving device for driving a vibration-type actuator disposed inside a magnetically shielded room, the driving device comprising:
the optical receiving circuit configured to receive a driving waveform for driving the vibration-type actuator as the optical pulse signal according to claim 1; and
a linear amplifier configured to receive a signal based on the non-pulse signal output from the optical receiving circuit and output a driving voltage to be applied to the vibration-type actuator.

8. The driving device according to claim 7, wherein the driving waveform is a pulse signal in which a sine wave is pulse-modulated.

9. The driving device according to claim 7, wherein the linear amplifier has a filter characteristic.

10. The driving device according to claim 8, wherein the optical receiving circuit and the linear amplifier are configured to output a signal that contains at least a fundamental wave component of the sine wave.

11. A system comprising:
the vibration-type actuator and the driving device for the vibration-type actuator according to claim 7;
a waveform generating unit configured to generate a pulse signal in which waveform data is pulse-modulated as the driving waveform; and
an optical transmitting circuit configured to convert the driving waveform into an optical pulse signal,
wherein the waveform generating unit includes a compensator configured to correct the waveform data for use in compensating for linearity in photoelectric conversion performed by the optical receiving circuit.

12. The system according to claim 11, further comprising a receiving portion configured to irradiate a specimen with an electromagnetic wave and receive the electromagnetic wave from the specimen,
wherein the vibration-type actuator, the driving device for the vibration-type actuator, and the receiving portion are disposed inside a magnetically shielded room, and
the waveform generating unit and the optical transmitting circuit are disposed outside the magnetically shielded room.

13. The system according to claim 12, further comprising a magnetic resonance imaging (MRI) apparatus configured to obtain information on the specimen using a reception signal from the receiving portion.
